(19) United States
(12) Patent Application Publication
(10) Pub. No.: US 2023/0263010 A1
(43) Pub. Date: Aug. 17, 2023

(54) DISPLAY PANEL AND METHOD OF MANUFACTURING SAME

(71) Applicant: WUHAN CHINA STAR OPTOELECTRONICS SEMICONDUCTOR DISPLAY TECHNOLOGY CO., LTD., Wuhan (CN)

(72) Inventors: Lei Lv, Wuhan (CN); Meng Jin, Wuhan (CN); Tao Yuan, Wuhan (CN); Jinchang Huang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/309,871

(22) PCT Filed: Mar. 30, 2021
(86) PCT No.: PCT/CN2021/083754

§ 371 Date: Jun. 24, 2021

(30) Foreign Application Priority Data
Mar. 9, 2021 (CN) 202110257531.9

(51) Int. Cl. H10K 59/122; H10K 59/12; H10K 71/16; H10K 59/80; H10K 59/35

(52) U.S. Cl. CPC H10K 59/122; H10K 59/352; H10K 59/353; H10K 59/875; H10K 59/1201; H10K 71/16

(57) ABSTRACT

A display panel and a method of manufacturing the display panel are disclosed. By providing a cathode inhibition layer, when a cathode layer is formed by a full-surface vapor deposition process, the cathode layer deposited on the cathode inhibition layer is thinner, or no cathode layer is deposited on the cathode inhibition layer, so as to greatly improve light transmittance of a light-transmissive area. In addition, an area ratio of the cathode inhibition layer and a first display area is specifically set. In this manner, light transmittance of the first display area can be increased as much as possible based on a premise of ensuring a normal display of the first display area.

### BACKGROUND OF INVENTION

### 1. Field of Invention

The present invention relates to a technical field of displays, and particularly to, a display panel and a method of manufacturing the same.

### 2. Related Art

Organic light-emitting diode (OLED) display technologies have received more and more attention from scientific researchers, and have been widely used in display fields such as mobile phones, flat panels, and televisions. With rapid development of display devices, users have higher and higher requirements for screen aspect ratios of display devices, making large-size and high-resolution comprehensive display devices the future development direction.

In prior art, in order to increase screen aspect ratios as much as possible, optical components, such as front cameras and facial recognition components, are generally disposed under screens. However, in current OLED full-screen display devices, cathodes are prepared through full-surface formation, but the cathodes have low light transmittance, which causes the optical elements disposed under the screens to fail to receive sufficient light signals, thereby adversely affecting a normal operation of the optical elements.

A technical problem in current OLED full-screen display devices is that cathodes are prepared through full-surface formation, but the cathodes have low light transmittance, which causes the optical elements disposed under the screens to fail to receive sufficient light signals, thereby adversely affecting a normal operation of the optical elements.

### SUMMARY OF INVENTION

An object of the present invention is to provide a display panel and a method of manufacturing the display panel to overcome a problem that optical elements disposed under screens fail to receive sufficient light signals, thereby adversely affecting a normal operation of the optical elements.

In a first aspect, an embodiment of the present invention provides a display panel, comprising a first display area and a second display area; a substrate; a pixel definition layer disposed on a side of the substrate and comprising a plurality of pixel openings spaced apart from each other; wherein a cathode inhibition layer made of a light-transmissive material is disposed between adjacent ones of the pixel openings and located on a side of the pixel definition layer away from the substrate in the first display area, and an orthographic projection of the cathode inhibition layer on the substrate having an area smaller than or equal to 0.95 times an area of the first display area.

Optionally, the area of the orthographic projection of the cathode inhibition layer on the substrate is larger than or equal to 0.05 times the area of the first display area.

Optionally, the display panel further comprises a cathode layer disposed on a side of the pixel definition layer away from the substrate, wherein the cathode layer comprises a plurality of electrode portions corresponding to the pixel openings, respectively, and a plurality of bridging portions each configured to connect adjacent ones of the electrode portions and located in the first display area.

Optionally, the bridging portions are integrally formed with the electrode portions, the cathode inhibition layer comprises a plurality of light-transmissive blocks spaced apart from each other, and the first display area comprises a bridging region defined between adjacent ones of the electrode portions, wherein each of the bridging portions is located in the bridging region.

Optionally, the first display area comprises a plurality of light-transmissive partitioned areas, and each of the light-transmissive partitioned areas is defined between the bridging portions and a first pixel opening, a second pixel opening, a third pixel opening, and a fourth pixel opening included in the pixel openings; wherein the second pixel opening and the first pixel opening are located adjacent to each other and arranged in a first direction on a side of the first pixel opening, the third pixel opening and the second pixel opening are located adjacent to each other and arranged in a second direction on a side of the second pixel opening, the fourth pixel opening is located adjacent to the first pixel opening and the third pixel opening, and the light-transmissive blocks correspond to the light-transmissive partitioned areas, respectively.

Optionally, each of the light-transmissive blocks comprises a platform portion and an edge portion adjoining an edge of the platform portion, wherein an orthographic projection of the platform portion on the substrate is spaced apart from an orthographic projection of an adjacent one of the pixel openings on the substrate at a distance greater than or equal to a width of the edge portion.

Optionally, the width of the edge portion is between two microns (µm) and five µm.

Optionally, the orthographic projection of the platform portion on the substrate has an area larger than or equal to 0.84 times the area of the first display area.

Optionally, the distance between the orthographic projection of the platform portion on the substrate and the orthographic projection of the adjacent one of the pixel openings is between two µm and ten µm.

Optionally, the orthographic projection of the platform portion on the substrate has an area larger than or equal to 0.64 times the area of the first display area.

Optionally, the orthographic projection of the platform portion on the substrate has an area smaller than or equal to 0.9 times the area of the first display area.

Optionally, an orthographic projection of the light-transmissive block on the substrate is spaced apart from an orthographic projection of a cathode included in the display panel.

Optionally, the orthographic projection of the platform portion on the substrate has a shape adapted to a shape of a corresponding one of the light-transmissive partitioned areas.

Optionally, a profile of the orthographic projection of the platform portion on the substrate is curved in shape.

In a second aspect, an embodiment of the present application further provides a display panel, comprising a first display area and a second display area; a substrate; a pixel definition layer disposed on a side of the substrate and comprising a plurality of pixel openings spaced apart from each other; wherein a cathode inhibition layer made of a light-transmissive material is disposed between adjacent ones of the pixel openings and located on a side of the pixel definition layer away from the substrate in the first display area, and an orthographic projection of the cathode inhibition layer on the substrate having an area smaller than or equal to 0.95 times an area of the first display area; wherein the area of the orthographic projection of the cathode inhibition layer on the substrate is larger than or equal to 0.05 times the area of the display area.

Optionally, the display panel further comprises a cathode layer disposed on a side of the pixel definition layer away from the substrate, wherein the cathode layer comprises a plurality of electrode portions corresponding to the pixel openings, respectively, and a plurality of bridging portions each configured to connect adjacent ones of the electrode portions and located in the first display area.

Optionally, the bridging portions are integrally formed with the electrode portions, the cathode inhibition layer comprises a plurality of light-transmissive blocks spaced apart from each other, and the first display area comprises a bridging region defined between adjacent ones of the electrode portions, wherein each of the bridging portions is located in the bridging region.

Optionally, the first display area comprises a plurality of light-transmissive partitioned areas, and each of the light-transmissive partitioned areas is defined between the bridging portions and a first pixel opening, a second pixel opening, a third pixel opening, and a fourth pixel opening included in the pixel openings; wherein the second pixel opening and the first pixel opening are located adjacent to each other and arranged in a first direction on a side of the first pixel opening, the third pixel opening and the second pixel opening are located adjacent to each other and arranged in a second direction on a side of the second pixel opening, the fourth pixel opening is located adjacent to the first pixel opening and the third pixel opening, and the light-transmissive blocks correspond to the light-transmissive partitioned areas, respectively.

Optionally, each of the light-transmissive blocks comprises a platform portion and an edge portion adjoining an edge of the platform portion, wherein an orthographic projection of the platform portion on the substrate is spaced apart from an orthographic projection of an adjacent one of the pixel openings at a distance greater than or equal to a width of the edge portion.

In a third aspect, an embodiment of the present application provides a method of manufacturing a display panel, the display panel comprising a first display area and a second display area, and the method of manufacturing the display panel comprising: S10: forming a pixel definition layer on a side of a substrate, wherein the pixel definition layer comprises a plurality of pixel openings spaced apart from each other; and S20: forming a cathode inhibition layer between adjacent ones of the pixel openings on a side of the pixel definition layer away from the substrate, wherein the cathode inhibition layer is made of a light-transmissive material and is located in the first display area, and an orthographic projection of the cathode inhibition layer on the substrate having an area smaller than or equal to 0.95 times an area of the first display area.

The present application has advantageous effects as follows: by providing the cathode inhibition layer having a small adhesion or even being repellent to the cathode layer, when the cathode layer is formed by a full-surface vapor deposition process, the cathode layer deposited on the cathode inhibition layer or in the light-transmissive area is thinner, or no cathode layer is deposited on the cathode inhibition layer, so that the light transmittance of the first display area is improved without changing a manufacturing process of the cathode layer, and optical elements arranged in the first display area can receive sufficient light signals. In addition, an area ratio of the cathode inhibition layer and the first display area is specifically set. In this manner, the light transmittance of the first display area can be increased as much as possible based on a premise of ensuring a normal display of the first display area.

### BRIEF DESCRIPTION OF DRAWINGS

To better illustrate embodiments or technical solutions in the prior art, a brief description of the drawings used in the embodiments will be given below. Obviously, the accompanying drawings in the following description merely show certain embodiments of the present invention, and those skilled in the art may still derive other drawings from these accompanying drawings without creative efforts.

FIG. 1 is a schematic plan view of a display panel in accordance with an embodiment of the present application.

FIG. 2 is a schematic structural view of the display panel in accordance with the embodiment of the present application.

FIG. 3 is a schematic view showing an arrangement of an anode and light-transmissive blocks of a first subpixel in accordance with the embodiment of the present application.

FIG. 4 is a schematic view showing an arrangement of an anode and light-transmissive blocks of a first subpixel in accordance with an embodiment of the present application.

FIG. 5 is a schematic view showing an arrangement of an anode and light-transmissive blocks of a first subpixel in accordance with an embodiment of the present application.

FIG. 6 is a schematic view showing an arrangement of an anode and light-transmissive blocks of a first subpixel in accordance with an embodiment of the present application.

FIG. 7 is a schematic view showing an arrangement of an anode and light-transmissive blocks of a first subpixel in accordance with an embodiment of the present application.

FIG. 8 is a schematic view showing an arrangement of an anode and light-transmissive blocks of a first subpixel in accordance with an embodiment of the present application.

FIG. 9 is a schematic view showing an arrangement of an anode and light-transmissive blocks of a first subpixel in accordance with an embodiment of the present application.

FIG. 10 is a schematic view showing an arrangement of an anode and light-transmissive blocks of a first subpixel in accordance with an embodiment of the present application.

FIG. 11 is a schematic structural view of a display panel in accordance with the embodiment of the present application.

FIG. 12 is a flowchart of a method of manufacturing a display panel in accordance with an embodiment of the present application.

Description of reference signs of the accompanying drawings: first display area 11; light-emitting area 111; light-transmissive area 112; second display area 12; first subpixel 13; anode 131; light-emitting layer 132; cathode layer 133; bridging portion 133a; first auxiliary layer 134; second auxiliary layer 135; second subpixel 14; substrate 15; array layer 16; active layer 161; first insulating layer 162; first gate electrode 163; second insulating layer 164; second gate electrode 165; interlayer dielectric layer 166; source/drain metal layer 167; planarization layer 168; pixel definition layer 17; pixel opening 171; cathode inhibition layer 18; light-transmissive block 181; platform portion 181a; edge portion 181b

### DESCRIPTION OF PREFERRED EMBODIMENTS

The technical solutions in the embodiments of the present application will be clearly and completely described in the following with reference to the accompanying drawings in the embodiments. Apparently, the embodiments as described are only a part, but not all, of the embodiments of the present application. Based on the embodiments in the present application, all other embodiments obtained by those skilled in the art without creative efforts shall be within the scope of the present application. In addition, it should be understood that the specific implementations described here are only used to illustrate and explain the application, and are not used to limit the application. In this application, unless otherwise stated, the directional words, such as “upper” and “lower” generally refer to the upper and lower directions of the device in actual use or working state, and specifically refer to the drawing directions in the drawings, while “inner” and “outer” refer to the outline of the device.

Embodiments of the present application provide a display panel and a manufacturing method thereof. Detailed descriptions are given below. It should be noted that the order of description in the following embodiments is not meant to limit the preferred order of the embodiments.

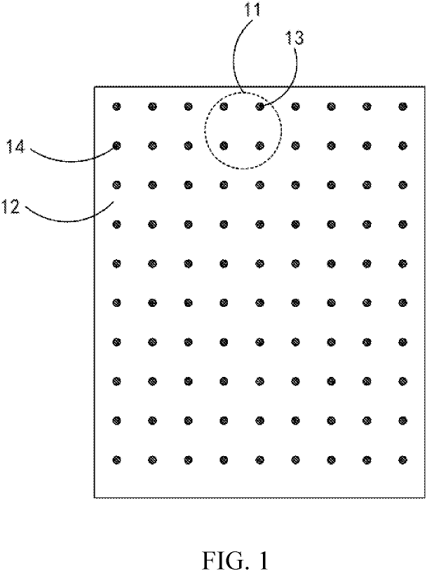

An embodiment of the present application provides a display panel. As shown in FIG. 1, the display panel includes a first display area 11 and a second display area 12 surrounding at least part of the first display area 11, and the first display area 11 may be formed anywhere on the display panel.

Specifically, the display panel is a full-screen display panel. A plurality of first subpixels 13 are arranged in the first display area 11, and a plurality of second subpixels 14 are arranged in the second display area 12.

It should be noted that the first display area 11 is an additional function area and can be used not only to display images, so that the display panel can present a full-screen display effect, but to allow installation of optical components, such as cameras, optical touch components, and fingerprint recognition sensors, thereby improving user experience. The second display area 12 is a main display area and is configured to display images.

It should also be noted that display brightness in the first display area 11 may be same as or different from display brightness in the second display area 12. The display brightness in the first display area 11 and the second display area 12 can be adjusted by modifying factors, such as size of driving current and light transmittance.

In one embodiment, light transmittance of the first display area 11 is greater than light transmittance of the second display area 12.

It can be understood that for optical elements, the light transmittance of the first display area 11 has a great influence on the operation of the optical elements, and the light transmittance of the first display area 11 is related to a film structure of the first display area 11. Taking the optical element as a camera as an example, the higher the light transmittance of the first display area 11 is, the better the imaging quality of the camera is when performing shooting work.

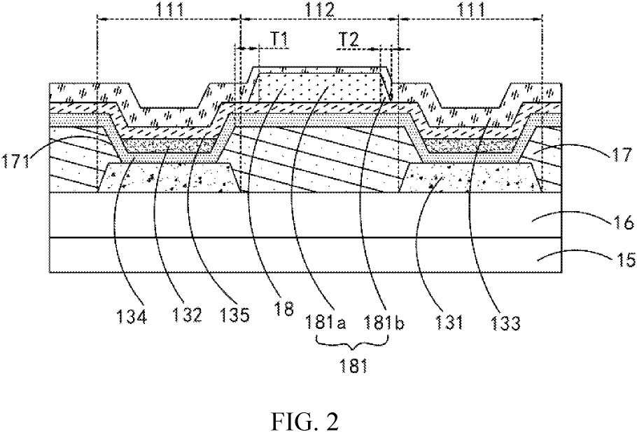

As shown in FIG. 2, in the embodiment of the present application, the display panel includes a substrate 15, a pixel definition layer 17 disposed on a side of the substrate 15, and a cathode layer 133 disposed on a side of the pixel definition layer 17 away from the substrate 15. A plurality of pixel openings 171 are spaced apart from each other and formed in the pixel definition layer 17.

In one embodiment, the substrate 15 may be a flexible substrate, and a material of the flexible substrate may be an organic material such as polyimide. The substrate 15 may also be a rigid substrate. The rigid substrate may be made of, for example, glass, metal, plastic, etc. The substrate 15 may be a single-layer film structure or a multi-layer film structure.

In one embodiment of the present application, a cathode inhibition layer 18 made of a light-transmissive material is disposed between adjacent ones of the pixel openings 171 and located on a side of the pixel definition layer 17 away from the substrate 15 in the first display area 11.

It should be noted that by providing the cathode inhibition layer 18 having a small adhesion or even being repellent to the cathode layer 133, when the cathode layer 133 is formed by a full-surface vapor deposition process, due to an adhesion force between the cathode layer 133 and other film layers being greater than an adhesive force of the cathode layer 133 and the cathode inhibition layer 18, the cathode layer 133 deposited on the cathode inhibition layer 18 is thinner, or no cathode layer 133 is deposited on the cathode inhibition layer 18, so that the light transmittance of the first display area 11 is improved without changing a manufacturing process of the cathode layer 133, and the optical elements arranged in the first display area 11 can receive sufficient light signals.

In one embodiment, the cathode layer 133 may be made of metallic magnesium. The cathode inhibition layer 18 may be made at least one of BAlq (bis(2-methyl-8-hydroxyquinoline)-4-(p-phenylphenol) aluminum), TAZ (3-(Biphenyl-4-yl)-5-(4-tert-butylphenyl)-4-phenyl-4H-1,2,4-triazole), or OTI (indium oxide). Adhesion of metallic magnesium on BAlq, TAZ, and OTI is poor. When metal magnesium is deposited to form the cathode layer 133, the cathode inhibition layer 18 inhibits film formation of metal magnesium on the cathode inhibition layer 18.

Specifically, the display panel further includes an array layer 16 disposed on the substrate 15. Each of the first subpixels 13 includes an anode 131, a light-emitting layer 132, and the cathode layer 133. The anode 131 is disposed on a side of the array layer 16 away from the substrate 15, the light-emitting layer 132 is disposed on a side of the anode 131 away from the substrate 15, and the cathode layer 133 is disposed on a side of the light-emitting layer 132 away from the substrate 15.

In one embodiment of the present application, the first display area 11 includes a light-emitting area 111 and a light-transmissive area 112. The light-emitting area 111 is configured for image display, the light-transmissive area 112 is configured for transmitting external light to increase the light transmittance of the first display area 11, and the anode 131 is located in the light-emitting area 111.

In one embodiment, the first display area 11 includes a plurality of the light-emitting areas 111. The light-emitting areas 111 may communicate with each other to form a larger area display area, or may be spaced apart from each other. The first subpixels 13 are distributed in the light-emitting areas 111.

In one embodiment, the light-emitting areas 111 are evenly distributed in the first display area 11. The first subpixels 13 are in a one-to-one correspondence with the light-emitting areas 111, so that the first subpixels 13 are evenly distributed all over the first display area 11, thereby preventing a non-display situation or a poor display situation in a large area from occurring due to display concentration, so as to help improve the user experience.

In one embodiment, the light-transmissive area 112 may include a plurality of partitioned areas, which may be spaced from each other or communicate with each other.

Specifically, the cathode inhibition layer 18 is located in the light-transmissive area 112 in the first display area 11. Part of a thickness of the cathode layer 133 with respect to the cathode inhibition layer 18 is less than part of a thickness of the cathode layer 133 with respect to the pixel openings 171.

In one embodiment, the anode 131 is disposed on the side of the array layer 16 away from the substrate 15. The pixel definition layer 17 is disposed on a side of both the array layer 16 and the anode 131 away from the substrate 15. The pixel openings 171 are in a one-to-one correspondence with the anodes 131. By uncovering part of the anode 131, each of the pixel openings 171 is located within the light-emitting area 111.

Specifically, the light-emitting layer 132 is an organic light-emitting material layer. The display panel further includes a first auxiliary layer 134 disposed on the side of the anode 131 away from the substrate 15, and a second auxiliary layer 135 disposed on a side of the first auxiliary layer 134 away from the substrate 15.

Specifically, the light-emitting layer 132 is located between the first auxiliary layer 134 and the second auxiliary layer 135 in the pixel opening 171. Part of the first auxiliary layer 134 is located on the pixel definition layer 17 and covers part of the anode 131 located in the pixel opening 171.

Specifically, the first auxiliary layer 134 may include a hole injection layer and a hole transport layer that are sequentially stacked in a direction away from the substrate 15, and the hole injection layer covers the anode 131. The second auxiliary layer 135 may include an electron transport layer and an electron injection layer that are sequentially stacked in the direction away from the substrate 15, and the electron transport layer covers the light-emitting layer 132.

In the embodiment of the present application, the first auxiliary layer 134 and the second auxiliary layer 135 are made of transparent materials, which have little influence on the light transmittance of the first display area 11. The first auxiliary layer 134 and the second auxiliary layer 135 may cover the light-emitting area 111 and the light-transmissive area 112.

It can be understood that, at this time, the cathode layer 133 and the cathode inhibition layer 18 are disposed on a side of the second auxiliary layer 135 away from the substrate 15, and the adhesive force of the cathode layer 133 and the cathode inhibition layer 18 is less than an adhesive force of the cathode layer 133 and the second auxiliary layer 135, so that part of a thickness of the cathode layer 133 with respect to the second auxiliary layer 135 is greater than the part of the thickness of the cathode layer 133 with respect to the cathode inhibition layer 18.

In one embodiment, the light-emitting layer 132 is only disposed in the light-emitting area 111, and the light-transmissive area 112 is not provided with the light-emitting layer 132, which can prevent the light-emitting layer 132 from adversely affecting light transmittance of the light-transmissive area 112 and help increase the light transmittance of the first display area 11.

In one embodiment, the part of the thickness of the cathode layer 133 with respect to the pixel openings 171 is greater than the part of the thickness of the cathode layer 133 with respect to the cathode inhibition layer 18, thereby preventing formation of an encapsulation layer from being adversely affected due to a large height difference formed between the cathode layer 133 and the cathode inhibition layer 18.

In the embodiment of the present application, an orthographic projection of the cathode inhibition layer 18 on the substrate 15 has an area smaller than or equal to 0.95 times an area of the first display area 11.

It can be understood that, theoretically, the larger the area of the cathode inhibition layer 18 is, the greater the light transmittance of the first display area 11 is. However, since it is necessary to provide a sufficient number of the first subpixels 13 in the first display area 11, and when the cathode inhibition layer 18 is used to thin or even remove the cathode layer 133 in the light-transmissive area 112, a thinning of the cathode layer 133 will increase resistance of the cathode layer 133 and affect electrical performance of the cathode layer 133, thereby adversely influencing a normal display of the first subpixels 13. Therefore, the area of the cathode inhibition layer 18 cannot be as large as desired. When the cathode inhibition layer 18 is provided all over the first display area 11 except for a region corresponding to the pixel openings 171, an area where the cathode inhibition layer 18 can be disposed is the largest at this time. The area of the orthographic projection of the cathode inhibition layer 18 on the substrate 15 is equal to 0.95 times the area of the first display area 11. At this time, the light transmittance of the first display area 11 can be increased as much as possible based on a premise of ensuring a normal display of the first display area 11.

Further, the area of the orthographic projection of the cathode inhibition layer 18 on the substrate 15 is larger than or equal to 0.05 times the area of the first display area 11.

It should be noted that the smaller the area of the cathode inhibition layer 18 is, the less the influence on the electrical performance of the cathode layer 133 and the first subpixels 13 is. However, the provision of the cathode inhibition layer 18 requires additional processes and materials, which will increase manufacturing cost of the display panel. If an area of the cathode inhibition layer 18 is too small, the light transmittance of the first display area 11 will increase less, which reduces cost performance of the cathode inhibition layer 18. When the area of the orthographic projection of the cathode inhibition layer 18 on the substrate 15 is smaller than 0.05 times the area of the first display area 11, an actual benefit brought by the provision of the cathode inhibition layer 18 would be less than the cost of providing the cathode inhibition layer 18.

As shown in FIGS. 2 to 11, in the embodiment of the present application, the cathode layer 133 includes a plurality of electrode portions in a one-to-one correspondence with the pixel openings 171, and a plurality of bridging portions 133a each configured to connect adjacent ones of the electrode portions and located in the first display area 11. The adjacent ones of the electrode portions are connected through the bridging portions 133a.

It should be noted that the electrode portions are in a one-to-one correspondence with the first subpixels 13. That is, each of the first subpixels 13 includes one of the electrode portions, and the electrode portions are arranged in a scattered manner, that is, the first subpixels 13 are arranged in the scattered manner, thereby preventing a non-display situation or a poor display situation in a large area from occurring due to display concentration. At a same time, by using the bridging portion 133a to connect the electrode portions, an overall resistance of the cathode layer 133 can be reduced, thereby reducing a difference in current magnitude between a central area and an edge area of the first display area 11 caused by a voltage drop, and improving uniformity of display brightness of the first display area 11.

Specifically, the electrode portions can be evenly distributed in the first display area 11 to improve the display uniformity of the first display area 11.

In one embodiment, the bridging portions 133a and the electrode portions are located in different layers, and the bridging portions 133a and the electrode portions may be made of same or different materials.

When the bridging portions 133a and the electrode portions are made of different materials, the bridging portions 133a can be made of a transparent conductive metal. The light transmittance of the first display area 11 can also be increased as the bridging portions 133a function to reduce the overall resistance of the cathode layer 133.

It should be noted that when forming the cathode layer 133 by a full-surface vapor deposition process, the cathode inhibition layer 18 is used to remove part of the cathode layer 133 outside the light-emitting area 111, leaving only part of the cathode layer 133 inside the light-emitting area 111, thereby further improving the light transmittance of the first display area 11.

In one embodiment, the bridging portions 133a and the electrode portions are arranged in a same layer, and the bridging portions 133a and the electrode portions may be made of same or different materials.

When the bridging portions 133a and the electrode portions are made of different materials, the bridging portions 133a can be made of a transparent conductive metal to greatly increase the light transmittance of the first display area 11, while using the bridging portions 133a to reduce the overall resistance of the cathode layer 133.

As shown in FIGS. 2 to 10, when the bridging portions 133a and the electrode portions are made of a same material, the bridging portions133a may be integrally formed with the electrode portions. The cathode inhibition layer 18 includes a plurality of light-transmissive blocks 181 spaced apart from each other, and the first display area 11 includes a bridging region defined between adjacent ones of the light-transmissive blocks 181, wherein each of the bridging portions 133a is located in the bridging region.

It should be noted that when the bridging portions 133a and the electrode portions are arranged in a same layer and made of a same material, the cathode inhibition layer 18 is provided to be composed of the spaced apart light-transmissive blocks 181. When the cathode layer 133 is formed all the first subpixels 13 by the full-surface vapor deposition process, a cathode material is deposited in the bridging region between adjacent ones of the light-transmissive blocks 181 at the same time, so as to form the electrode portions and the bridging portions 133a connecting the electrode portions, thereby reducing the overall resistance of the cathode layer 133 without increasing a manufacturing process.

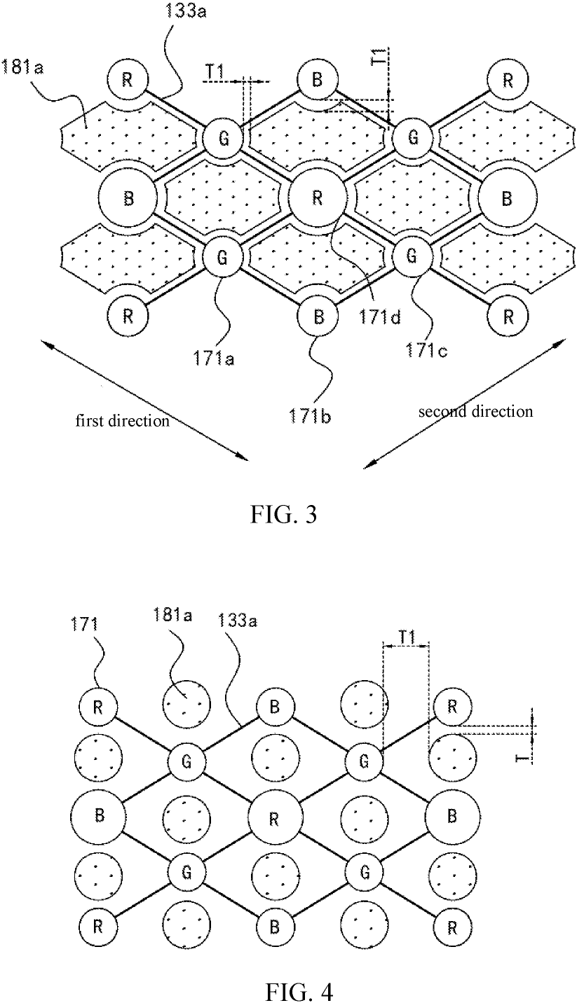

It should be noted that FIGS. 3 to 10 only illustrate an instance that a shape of the bridging portions 133a is a trace-like shape, which is only to better illustrate a positional relationship between the bridging portions 133a and the pixel openings 171. In actual implementation, when the cathode layer 133 is vapor-deposited on a front side, the cathode material is distributed in an entire bridging region, so that the bridging portions 133a distributed in the entire bridging region can be formed, and the bridging portions 133s have a same shape as that of the bridging region.

In one embodiment of the present application, the light-transmissive area 112 includes a plurality of light-transmissive partitioned areas. Each of the light-transmissive partitioned areas is defined between the bridging portions 133a and a first pixel opening 171a, a second pixel opening 171b, a third pixel opening 171c, and a fourth pixel opening 171d included in the pixel openings 171.

Specifically, the second pixel opening 171b and the first pixel opening 171a are located adjacent to each other and arranged in a first direction on a side of the first pixel opening 171a. The third pixel opening 171c and the second pixel opening 171b are located adjacent to each other and arranged in a second direction on a side of the second pixel opening 171b. The fourth pixel opening 171d is located adjacent to the first pixel opening 171a and the third pixel opening 171c. The light-transmissive blocks 181 are disposed in a one-to-one correspondence with the light-transmissive partitioned areas.

It should be noted that, with reference to FIG. 3, each of the light-transmissive partitioned areas is surrounded by four of the pixel openings 171 and four of the bridging portions 133a adjacent to one another in sequence.

It should also be noted that the first direction and the second direction are different directions, that is, the first direction crosses the second direction. As shown in FIG. 3, in FIG. 3, the first direction is parallel with a length of the bridging portion 133a between the first pixel opening 171a and the second pixel opening 171b, and the second direction is parallel with a length of another bridging portion 133a between the second pixel opening 171b and the third pixel opening 171c.

It can be understood that positions of the pixel openings 171 are positions of the first subpixels 13. By designing the positions of the first subpixels 13 and the light-transmissive blocks 181, distribution of the first subpixels 13 and the light-transmissive blocks 181 in the first display area 11 is more uniform, thereby ensuring uniformity of the display brightness and the light transmittance of the first display area 11.

Specifically, each of the light-transmissive blocks 181 is located in a corresponding one of the light-transmissive partitioned areas, thereby reserving sufficient space for the arrangement of the bridging portions 133a, and preventing formation of the bridging portions 133a from failing after adjacent ones of the light-transmissive blocks 181 are connected, as well as preventing the provision of the cathode inhibition layer 18 from causing interference and adverse effects on displaying in the first display area 11.

Specifically, the arrangement of the light-transmissive blocks 181 is related to the arrangement of the first subpixels 13. When the first subpixels 13 are evenly arranged, the light-transmissive blocks 181 are evenly arranged. When the first subpixels 13 are randomly arranged, the light-transmissive blocks 181 are randomly arranged. The arrangement of the first subpixels 13 can be selected according to actual conditions.

In one embodiment, each of the light-transmissive blocks 181 includes a platform portion 181a and an edge portion 181b adjoining an edge of the platform portion 181a.

Specifically, an orthographic projection of the platform portion 181a on the substrate 15 is spaced apart from an orthographic projection of an adjacent one of the pixel openings 171 on the substrate 15 at a distance T1 greater than or equal to a width T2 of the edge portion 181b.

It should be noted that the platform portion 181a is an effective part of the light-transmissive block 181 to inhibit formation of the cathode material. The larger an area of the platform portion 181a is, the more the cathode layer being thinned or removed is. However, when the patterned cathode inhibition layer 18 is formed by vapor deposition using a mask, a conventional process will inevitably form a generally slope-shaped structure at an edge of the light-transmissive block 181, that is, the edge portion 181b is formed. If a cathode inhibition material falls into the pixel opening 171, it will affect the normal display of the first subpixel 13.

In the present application, by designing layout of the platform portions 181a of the light-transmissive blocks 181, the distance T1 between the platform portion 181a and adjacent one of the pixel openings 171 is greater than the width T2 of the edge portion 181b, thereby preventing the cathode inhibition layer 18 from falling into the pixel opening 171 during formation of the light-transmissive blocks 181.

In one embodiment, the width T2 of the edge portion 181b is between two microns (µm) and five µm. The width T2 of the edge portion 181b may be two µm, three µm, four µm, or five µm. That is, as the width T2 of the edge portion 181b is two µm, the distance T1 between the orthographic projection of the platform portion 181a on the substrate 15 and the orthographic projection of the adjacent one of the pixel openings 171 on the substrate 15 is greater than two µm. As the width T2 of the edge portion 181b is five µm, the distance T1 between the orthographic projection of the platform portion 181a on the substrate 15 and the orthographic projection of the adjacent one of the pixel openings 171 on the substrate 15 is greater than five µm.

It should be noted that the width T2 of the edge portion 181b depends on factors such as process accuracy and equipment accuracy. Theoretically, the smaller the width T2 of the edge portion 181b is, the larger an area for placing the platform portion 181a is, so that the light transmittance of the first display area 11 can be greater based on a premise of not affecting the normal display of the first subpixels 13.

Specifically, the area of the orthographic projection of the platform portion 181a on the substrate 15 is larger than or equal to 0.84 times the area of the first display area 11.

The area of the orthographic projection of the platform portion 181a on the substrate 15 is smaller than or equal to 0.90 times the area of the first display area 11.

It should be noted that when the width T2 of the edge portion 181b is five µm, an area for placing the platform portion 181a is the smallest. In this manner, the area of the orthographic projection of the platform portion 181a on the substrate 15 is 0.84 times the area of the first display area 11. When the width T2 of the edge portion 181b is two µm, an area for placing the platform portion 181a is the largest. In this manner, the area of the orthographic projection of the platform portion 181a on the substrate 15 is 0.90 times the area of the first display area 11.

In one embodiment, the distance T1 between the orthographic projection of the platform portion 181a on the substrate 15 and the orthographic projection of the adjacent one of the pixel openings 171 on the substrate 15 is between 2 µm and 10 µm. The distance T1 between the orthographic projection of the platform portion 181a on the substrate 15 and the orthographic projection of the adjacent one of the pixel openings 171 on the substrate 15 may be 2 µm, 3 µm, 5 µm, 8 µm, or 10 µm.

It should be noted that in actual processes, due to factors such as process accuracy, in order to prevent the edge portion 181b from falling into the pixel opening 171, a distance between the edge portion 181b and the pixel opening 171 also needs to be considered. The smaller the distance between the edge portion 181b and the pixel opening 17 is, the larger the area for placing the platform portion 181a is, but the greater the risk of the edge portion 181b falling into the pixel opening 171 is. Likewise, the greater the distance between the edge portion 181b and the pixel opening 17 is, the less the risk of the edge portion 181b falling into the pixel opening 171 is, but the smaller the area for placing the platform portion 181a is.

In this application, taking into consideration of factors such as the distance between the edge portion 181b and the pixel opening 171, the width of the edge portion 181b, and cost-effectiveness of providing the cathode inhibition layer 18, the distance between the platform portion 181a and the pixel opening 171 is reasonably set in order to reduce the risk of the edge portion 181b falling into the pixel opening 171 based on a premise that the first display area 11 having greater light transmittance is ensured.

Specifically, the area of the orthographic projection of the platform portion 181a on the substrate 15 is larger than or equal to 0.64 times the area of the first display area 11.

The area of the orthographic projection of the platform portion 181a on the substrate 15 is smaller than or equal to 0.90 times the area of the first display area 11.

It should be noted that when the distance T1 between the edge portion 181b and the pixel opening 171 is 5 µm, and the width T2 of the edge portion 181b is 5 µm, the area for displacing the platform portion 181a is the smallest. In this manner, the area of the orthographic projection of the platform portion 181a on the substrate 15 is 0.64 times the area of the first display area 11. When the distance T1 between the edge portion 181b and the pixel opening 171 is zero, and the width T2 of the edge portion 181b is 2 µm, the area for displacing the platform portion 181a is the largest. In this manner, the area of the orthographic projection of the platform portion 181a on the substrate 15 is 0.90 times the area of the first display area 11.

In one embodiment, an orthographic projection of the cathode inhibition layer 18 on the substrate 15 is spaced apart from an orthographic projection of the anode 131 on the substrate 15.

It should be noted that the orthographic projection of the anode 131 on the substrate 15 covers the orthographic projection of the pixel opening 171 on the substrate 15. In order to make sure the normal display of the first subpixels 13, it is necessary to ensure that the orthographic projection of the cathode layer 133 on the substrate 15 covers the orthographic projection of the pixel opening 171 on the substrate 15. By configuring the cathode inhibition layer 18 not to overlap the anode 131, the cathode inhibition layer 18 is ensured to be kept at a certain distance from the pixel opening 171, as well as ensuring that the orthographic projection of the cathode layer 133 on the substrate 15 can cover the orthographic projection of the pixel opening 171 on the substrate 15, thereby preventing the arrangement of the cathode inhibition layer 18 from causing interference and adverse effects on the display of the first display area 11.

It should also be noted that a sufficient distance between the light-transmissive block 181 and the pixel opening 171 is needed to facilitate the arrangement of the bridging portions 133a. By designing layout of the light-transmissive block 181 of the cathode inhibition layer 18, based on a premise that the first display area 11 has sufficient light transmittance, there may be sufficient spacing between the light-transmissive block 181 and the pixel opening 171 to arrange the bridging portion 133a.

In one embodiment, in respect of four of the pixel openings 171 surrounding to form the light-transmissive partitioned area, each of the pixel openings 171 corresponds to one of the first subpixels 13. Four of the first subpixels 13 correspond to the four of the pixel openings 171 surrounding to form the light-transmissive partitioned area include at least one red subpixel (“R” subpixel), one green subpixel (“G” sub-pixel) and one blue subpixel (“B” sub-pixel).

In one embodiment, as shown in FIG. 3, an orthographic projection of the platform portion 181a on the substrate 15 has a shape adapted to a shape of a corresponding one of the light-transmissive partitioned areas, so as to increase an area for placing the platform portion 181a based on a premise that an area of the light-transmissive partitioned area remains the same, thereby further improving the light transmittance of the first display area 11.

It can be understood that an orthographic projection of the platform portion on the substrate having a shape adapted to a shape of a corresponding one of the light-transmissive partitioned areas refers to a profile of the orthographic projection of the platform portion on the substrate having a shape adapted to a shape of a profile of the corresponding one of the light-transmissive partitioned areas. Furthermore, the profile of the orthographic projection of the platform portion on the substrate is configured with a plurality of sides each having a same shape as a shape of a corresponding one of sides of the profile of the corresponding light-transmissive partitioned area. As shown in FIG. 3, a shape of a profile of the light-transmissive partitioned area is an irregular quadrilateral shape formed by curving four corners of a rhombus. In this manner, a profile of an orthographic projection of a corresponding one of the platform portions on the substrate also has an irregular quadrilateral shape formed by curving four corners of a rhombus, and the four corners of the profile of the orthographic projection of the platform portion on the substrate have curved shapes same as curved shapes of the four corners of the profile of the light-transmissive partitioned area.

It can also be understood that when the light-transmissive partitioned area has other shapes, such that the profile of the light-transmissive partitioned area is regular trapezoidal in shape, the profile of the orthographic projection of the corresponding platform portion on the substrate is also regular trapezoidal in shape. In addition, an upper bottom of the profile of the light-transmissive partitioned area is corresponding to an upper bottom of the profile of the orthographic projection of the corresponding platform portion on the substrate, and a lower bottom of the profile of the light-transmissive partitioned area is corresponding to a lower bottom of the profile of the orthographic projection of the corresponding platform portion on the substrate. When the light-transmissive partitioned area is circular in shape, the shape, the orthographic projection of the corresponding platform portion on the substrate is also circular in shape, and so on, and other shapes will not be listed here.

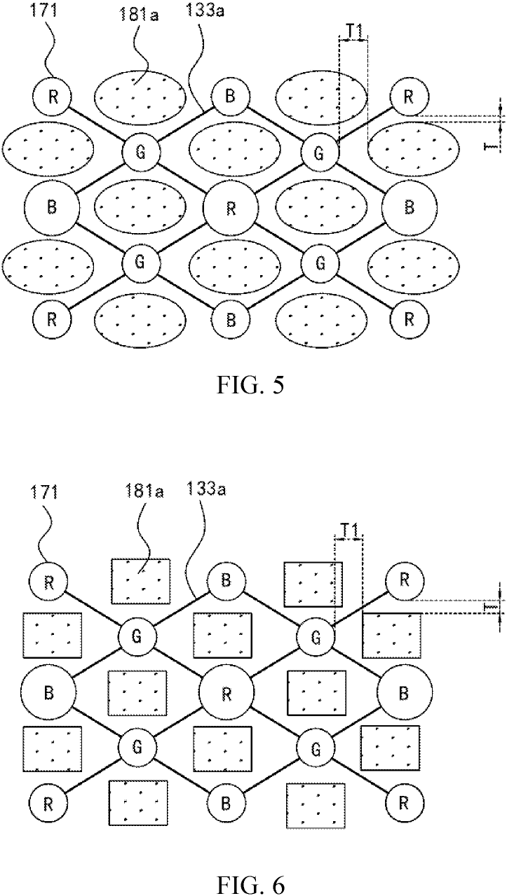

In one embodiment, as shown in FIGS. 4 and 5, a profile of an orthographic projection of the platform portion 181a on the substrate 15 is curved in shape. The profile of the orthographic projection of the platform portion 181a on the substrate 15 may be circular (FIG. 4), semicircular, elliptical (FIG. 5), or semi-elliptical in shape having curved sides.

It can be understood that during a preparation process of the cathode inhibition layer 18, a shape of the platform portion 181a is dependent on a shape of an opening of a mask configured for patterning, while the shape and accuracy of the opening is determined according to a process and accuracy of processing equipment. The more mature a process of forming a curved hole is, the higher processing accuracy is, so that a shape of a finally formed platform portion 181a has higher accuracy, thereby preventing the finally formed platform portion 181a from falling into the pixel opening 171, or preventing adjacent ones of the light-transmissive blocks 181 from being connected, and improving production yield of the display panel.

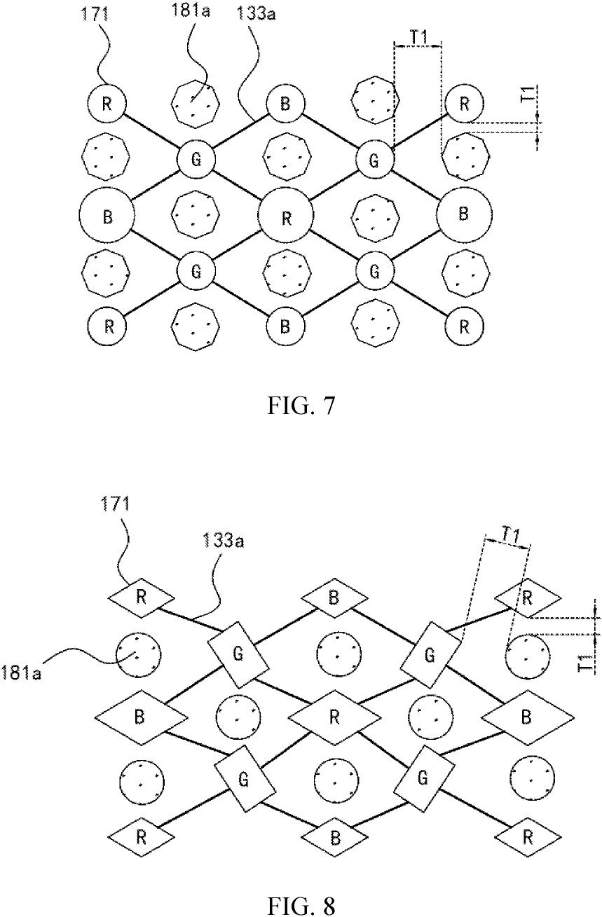

As shown in FIGS. 6 and 7, a shape of the profile of the orthographic projection of the platform portion 181a on the substrate 15 may also be regular or irregular non-curved shape, such as squares (FIG. 6), octagons (FIG. 7), or triangles.

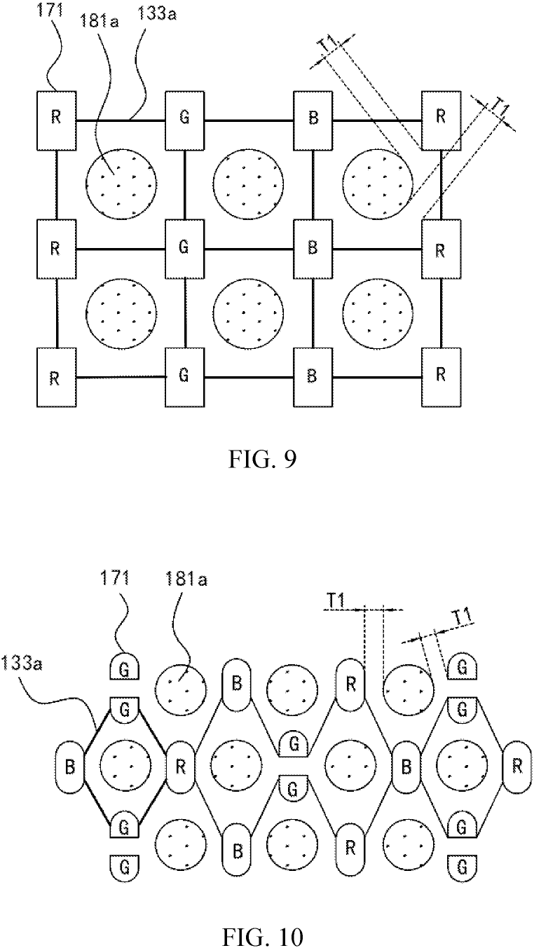

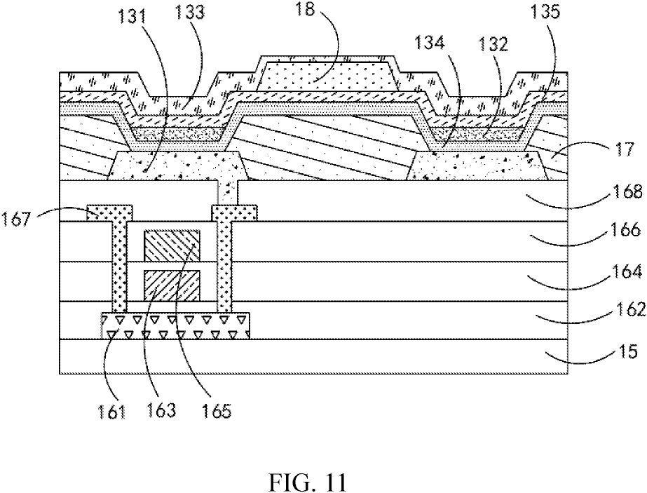

It should be noted that a shape of the pixel opening 171 is adapted to a shape of the first subpixel 13. FIGS. 3 to 7 only illustrate instances where the pixel opening 171 is circular in shape. In one embodiment, as shown in FIGS. 8 to 10, a shape of the pixel opening 171 can also be rhombuses (FIG. 8), squares (FIG. 9), or ovals (FIG. 10), etc. Each of the pixel openings 171 may have a same or different shape.

It can be understood that FIGS. 8 to 9 only illustrate an instance where profiles of the orthographic projections of the platform portions 181a on the substrate 15 are all circular in shape. In other embodiments, when a shape of the pixel opening 171 is a rhombus (FIG. 8), a square (FIG. 9), or an ellipse (FIG. 10), a profile of the orthographic projection of the platform portion 181a on the substrate 15 may also be elliptical, square, pentagonal, octagonal, or other shapes.

It should also be noted that FIGS. 3 to 10 only illustrate instances where a shape and size of all the platform portions 181a are the same. In one embodiment, a shape of each of the platform portions 181a may be totally different from each other, or may be partially different from each other. A size of each of the platform portions 181a may be totally different from each other, or may be partially different from each other.

It can be understood that the foregoing description illustrates a solution to increase the light transmittance of the first display area 11 by thinning or removing part of the cathode layer 133 in the first display area 11. It should also be noted that the light transmittance of the first display area 11 can also be adjusted by designing a density of the first subpixels 13.

Specifically, a pixel density in the first display area 11 may be same as a pixel density in the second display area 12, or may be different. For example, the pixel density in the first display area 11 may be less than the pixel density in the second display area 12 to increase the light transmittance of the first display area 11.

As shown in FIG. 11, in one embodiment, the array layer 16 includes an active layer 161 disposed on the substrate 15, a first insulating layer 162 covering the active layer 161, a first gate electrode 163 disposed on a side of the first insulating layer 162 away from the active layer 161, a second insulating layer 164 covering the first gate electrode 163, a second gate electrode 165 disposed on a side of the second insulating layer 164 away from the substrate 15, an interlayer dielectric layer 166 covering the second gate electrode 165, a source/drain metal layer 167 disposed on a side of the interlayer dielectric layer 166 away from the substrate 15, and a planarization layer 168 covering the source/drain metal layer 167.

Specifically, the anode 131 and the pixel definition layer 17 are disposed on a side of the planarization layer 168 away from the substrate. The source/drain metal layer 167 includes a source and a drain, and the anode 131 is in contact with each of the source and the drain through via holes.

Based on the above-mentioned display panel, the present application further provides a method of manufacturing the display panel including the first display area 11 and the second display area 12.

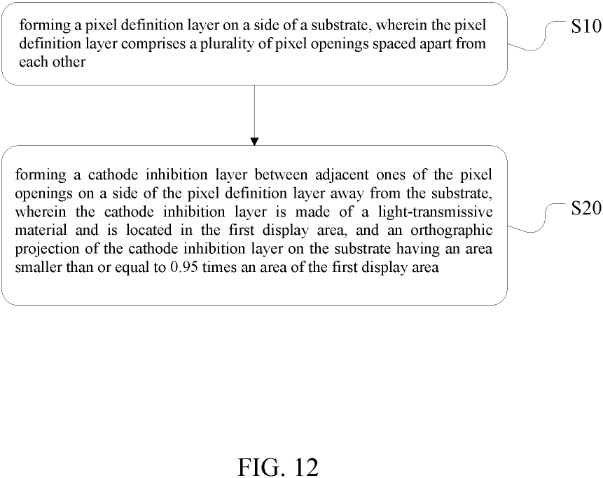

As shown in FIG. 12, the method of manufacturing the display panel includes steps as follows:

S10: forming a pixel definition layer 17 on a side of the substrate 15.

S20: forming a cathode inhibition layer 18 between adjacent ones of the pixel openings 171 on a side of the pixel definition layer 17 away from the substrate 15, wherein the cathode inhibition layer 18 is made of a light-transmissive material and is located in the first display area 11, and an orthographic projection of the cathode inhibition layer 18 on the substrate 15 having an area smaller than or equal to 0.95 times an area of the first display area 11.

In one embodiment, the area of the orthographic projection of the cathode inhibition layer 18 on the substrate 15 is larger than or equal to 0.05 times the area of the first display area 11.

In one embodiment, the display panel further includes a cathode layer 133 disposed on the side of the pixel definition layer 17 away from the substrate 15. The cathode layer 133 includes a plurality of electrode portions in a one-to-one correspondence with the pixel openings 171, and a plurality of bridging portions 133a each configured to connect adjacent ones of the electrode portions and located in the first display area 11.

In one embodiment, the bridging portions 133a are integrally formed with the electrode portions. The cathode inhibition layer 18 includes a plurality of light-transmissive blocks 181 spaced apart from each other, and the first display area 11 includes a bridging region defined between adjacent ones of the light-transmissive blocks 181, wherein each of the bridging portions 133a is located in the bridging region.

In one embodiment, the first display area 11 includes a plurality of light-transmissive partitioned areas. Each of the light-transmissive partitioned areas is defined between the bridging portions 133a and a first pixel opening 171a, a second pixel opening 171b, a third pixel opening 171c, and a fourth pixel opening 171d included in the pixel openings 171.

Specifically, the second pixel opening 171b and the first pixel opening 171a are located adjacent to each other and arranged in a first direction on a side of the first pixel opening 171a. The third pixel opening 171c and the second pixel opening 171b are located adjacent to each other and arranged in a second direction on a side of the second pixel opening 171b. The fourth pixel opening 171d is located adjacent to the first pixel opening 171a and the third pixel opening 171c. The light-transmissive blocks 181 are disposed in a one-to-one correspondence with the light-transmissive partitioned areas.

In one embodiment, each of the light-transmissive blocks 181 includes a platform portion 181a and an edge portion 181b adjoining an edge of the platform portion 181a.

Specifically, an orthographic projection of the platform portion 181a on the substrate 15 is spaced apart from an orthographic projection of an adjacent one of the pixel openings 171 on the substrate 15 at a distance greater than or equal to a width of the edge portion 181b.

In one embodiment, the width of the edge portion 181b is between two µm and five µm.

In one embodiment, the area of the orthographic projection of the platform portion 181a on the substrate 15 is larger than or equal to 0.84 times the area of the first display area 11.

In one embodiment, the distance between the orthographic projection of the platform portion 181a on the substrate 15 and the orthographic projection of the adjacent one of the pixel openings 171 on the substrate 15 is between 2 µm and 10 µm.

In one embodiment, the area of the orthographic projection of the platform portion 181a on the substrate 15 is larger than or equal to 0.64 times the area of the first display area 11.

In one embodiment, the area of the orthographic projection of the platform portion 181a on the substrate 15 is smaller than or equal to 0.90 times the area of the first display area 11.

In one embodiment, an orthographic projection of the light-transmissive block 181 on the substrate 15 is spaced apart from an orthographic projection of the cathode 131 on the substrate 15.

In one embodiment, the orthographic projection of the platform portion 181a on the substrate 15 has a shape adapted to a shape of a corresponding one of the light-transmissive partitioned areas.

In one embodiment, the orthographic projection of the platform portion 181a on the substrate 15 is curved in shape.

Specific examples are used in this article to explain the principles and implementation of this application. The descriptions of the above embodiments are only used to help understand the technical solutions and core ideas of this application. Also, for those skilled in the art, according to the idea of this application, there will be changes in the specific implementation and application scope. In summary, the content of this application should not be construed as a limitation on this application.

What is claimed is:

1. A display panel, comprising:
a first display area and a second display area;
a substrate;
a pixel definition layer disposed on a side of the substrate and comprising a plurality of pixel openings spaced apart from each other;
wherein a cathode inhibition layer made of a light-transmissive material is disposed between adjacent ones of the pixel openings and located on a side of the pixel definition layer away from the substrate in the first display area, and an orthographic projection of the cathode inhibition layer on the substrate having an area smaller than or equal to 0.95 times an area of the first display area.

2. The display panel of claim 1, wherein the area of the orthographic projection of the cathode inhibition layer on the substrate is larger than or equal to 0.05 times the area of the first display area.

3. The display panel of claim 2, further comprising a cathode layer disposed on a side of the pixel definition layer away from the substrate, wherein the cathode layer comprises a plurality of electrode portions corresponding to the pixel openings, respectively, and a plurality of bridging portions each configured to connect adjacent ones of the electrode portions and located in the first display area.

4. The display panel of claim 3, wherein the bridging portions are integrally formed with the electrode portions, the cathode inhibition layer comprises a plurality of light-transmissive blocks spaced apart from each other, and the first display area comprises a bridging region defined between adjacent ones of the electrode portions, wherein each of the bridging portions is located in the bridging region.

5. The display panel of claim 4, wherein the first display area comprises a plurality of light-transmissive partitioned areas, and each of the light-transmissive partitioned areas is defined between the bridging portions and the pixel openings comprising a first pixel opening, a second pixel opening, a third pixel opening, and a fourth pixel opening;
wherein the second pixel opening and the first pixel opening are located adjacent to each other and arranged in a first direction on a side of the first pixel opening, the third pixel opening and the second pixel opening are located adjacent to each other and arranged in a second direction on a side of the second pixel opening, the fourth pixel opening is located adjacent to the first pixel opening and the third pixel opening, and the light-transmissive blocks correspond to the light-transmissive partitioned areas, respectively.

6. The display panel of claim 5, wherein each of the light-transmissive blocks comprises a platform portion and an edge portion adjoining an edge of the platform portion, wherein an orthographic projection of the platform portion on the substrate is spaced apart from an orthographic projection of an adjacent one of the pixel openings at a distance greater than or equal to a width of the edge portion.

7. The display panel of claim 6, wherein the edge portion has a width between two microns (µm) and five µm.

8. The display panel of claim 7, wherein the orthographic projection of the platform portion on the substrate has an area larger than or equal to 0.84 times the area of the first display area.

9. The display panel of claim 6, wherein the distance between the orthographic projection of the platform portion on the substrate and the orthographic projection of the adjacent one of the pixel openings is between two µm and ten µm.

10. The display panel of claim 9, wherein the orthographic projection of the platform portion on the substrate has an area larger than or equal to 0.64 times the area of the first display area.

11. The display panel of claim 10, wherein the orthographic projection of the platform portion on the substrate has an area smaller than or equal to 0.9 times the area of the first display area.

12. The display panel of claim 6, wherein an orthographic projection of the light-transmissive block on the substrate is spaced apart from an orthographic projection of a cathode included in the display panel.

13. The display panel of claim 6, wherein the orthographic projection of the platform portion on the substrate matches has a shape adapted to a shape of a corresponding one of the light-transmissive partitioned areas.

14. The display panel of claim 6, wherein the orthographic projection of the platform portion on the substrate is arc-like in shape.

15. A display panel, comprising:
a first display area and a second display area;
a substrate;
a pixel definition layer disposed on a side of the substrate and comprising a plurality of pixel openings spaced apart from each other;
wherein a cathode inhibition layer made of a light-transmissive material is disposed between adjacent ones of the pixel openings and located on a side of the pixel definition layer away from the substrate in the first display area, and an orthographic projection of the cathode inhibition layer on the substrate having an area smaller than or equal to 0.95 times an area of the first display area;
wherein the area of the orthographic projection of the cathode inhibition layer on the substrate is larger than or equal to 0.05 times the area of the display area.

16. The display panel of claim 15, further comprising a cathode layer disposed on a side of the pixel definition layer away from the substrate, wherein the cathode layer comprises a plurality of electrode portions corresponding to the pixel openings, respectively, and a plurality of bridging portions each configured to connect adjacent ones of the electrode portions and located in the first display area.

17. The display panel of claim 16, wherein the bridging portions are integrally formed with the electrode portions, the cathode inhibition layer comprises a plurality of light-transmissive blocks spaced apart from each other, and the first display area comprises a bridging region defined between adjacent ones of the electrode portions, wherein each of the bridging portions is located in the bridging region.

18. The display panel of claim 17, wherein the first display area comprises a plurality of light-transmissive partitioned areas, and each of the light-transmissive partitioned areas is defined between the bridging portions and the pixel openings comprising a first pixel opening, a second pixel opening, a third pixel opening, and a fourth pixel opening;
wherein the second pixel opening and the first pixel opening are located adjacent to each other and arranged in a first direction on a side of the first pixel opening, the third pixel opening and the second pixel opening are located adjacent to each other and arranged in a second direction on a side of the second pixel opening, the fourth pixel opening is located adjacent to the first pixel opening and the third pixel opening, and the light-transmissive blocks correspond to the light-transmissive partitioned areas, respectively.

19. The display panel of claim 18, wherein each of the light-transmissive blocks comprises a platform portion and an edge portion adjoining an edge of the platform portion, wherein an orthographic projection of the platform portion on the substrate is spaced apart from an orthographic projection of an adjacent one of the pixel openings at a distance greater than or equal to a width of the edge portion.

20. A method of manufacturing a display panel, the display panel comprising a first display area and a second display area, and the method of manufacturing the display panel comprising:
S10: forming a pixel definition layer on a side of a substrate, wherein the pixel definition layer comprises a plurality of pixel openings spaced apart from each other; and
S20: forming a cathode inhibition layer between adjacent ones of the pixel openings on a side of the pixel definition layer away from the substrate, wherein the cathode inhibition layer is made of a light-transmissive material and is located in the first display area, and an orthographic projection of the cathode inhibition layer on the substrate having an area smaller than or equal to 0.95 times an area of the first display area.
